(19) United States
(12) Patent Application Publication
(10) Pub. No.: US 2008/0023677 A1
(43) Pub. Date: Jan. 31, 2008

(54) Functionalized Electroactive Polymers

(75) Inventors: Jean M.J. Frechet, Oakland, CA (US); Jinsong Liu, Albany, CA (US); Toru Tanaka, Ibaraki (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: The Regent Of The University Of California, Oakland, CA (US)

(21) Appl. No.: 11/587,728

(22) PCT Filed: Apr. 22, 2005
(86) PCT No.: PCT/US05/13873

§ 371 Date: Oct. 26, 2006

Related U.S. Application Data
(60) Provisional application No. 60/565,804, filed on Apr. 26, 2004.

(51) Int. Cl. H01B 1/12; C08G 75/00

(52) U.S. Cl. 252/517; 252/518.1; 252/519.4; 252/520.1; 252/520.2; 528/360; 528/380

(57) ABSTRACT

Novel thiophene polymers include homopolymers and random or alternating polymers. They may be included in electronic conducting devices such as photovoltaic cells, transistors and light emitters. The polymers provide improved performance in thin film transistors and electronic devices in which they are incorporated.

### BACKGROUND OF THE INVENTION

This invention relates to certain novel types of functionalized electroactive or conducting polymers, more particularly thiophene polymers and copolymers, and their use in devices including photovoltaic cells, light emitters, transistors, (including thin-film transistors) and the like.

The invention also relates to processes for preparing such polymers and copolymers, and for incorporating them into such devices.

The direct conversion of the light into electrical energy is accomplished in photovoltaic devices. Currently, most of the useful photovoltaics are silicon-based. Efficiency of the commercial cells reaches 17%, whereas as much as 25% efficiency can be achieved under the laboratory conditions. However, these devices remain expensive, due to the energy-demanding fabrication methods, involving high temperature, high vacuum, and stringent air-quality control. Silicon solar cells are also heavy and inflexible, thus limiting the portability of these devices. Finally, the performance of inorganic solar cells decreases with increase in operating temperature.

Several new alternatives to fully inorganic cells are now being developed. The most promising ones include dye-sensitized titania cells (a.k.a. Grätzel cells), fully organic cells, and hybrid solar cells, which combine inorganic and organic semiconductors. This invention is directed at this last category of photocells.

It is worth noting that sometimes different parameters are used to evaluate the cells. The external quantum efficiency (EQE), sometimes referred to as incident photon-to-current conversion efficiency (IPCE), evaluates the conversion of photons into current at a given wavelength. Usually (but not always), the IPCE curve is quite similar to the UV-vis absorbance spectrum of the light-absorbing entity. Maximum IPCE value is often reported. The overall power-conversion efficiency or white-light efficiency, is usually taken under standardized simulated sunlight (referred to as AM 1.5), is a true measure of the light-converting ability of the device.

The Grätzel cell consists of nanocrystalline TiO₂ film deposited onto the conducting glass electrode. Ruthenium dye is used to sensitize the wide bandgap TiO₂ semiconductor to the visible light. The regeneration of the oxidized dye is accomplished by iodine/triiodide redox electrolyte, which shuttles electrons from the Pt counter-electrode. Electrical load, connected to conducting glass electrode and to Pt counter-electrode, completes the circuit. The maximum IPCE is over 85%, whereas best power conversion efficiency is 10.4%, making this cell comparable to silicon-based photovoltaics. These high values are attributed to the almost 100% efficiency of the electron injection from the excited Ru dye into TiO₂, and to the very slow charge recombination.

However, since its inception more than 10 years ago, no seminal improvements have been made to the cell. The Grätzel cell has not been widely commercialized yet, in large part due to the presence of the liquid electrolyte, which is corrosive and can leak. Most applications require efficient large-area multi-cell modules, which should be simple to construct and connect. The liquid electrolyte makes manufacturing of these multi-cell modules difficult, since the cells must be electrically connected, yet chemically separated, preferably, on the same substrate. Even though the performance of the Grätzel cell does not decrease with increase in temperature, thermal expansion of the electrolyte and consequent leakage are detrimental to the cell's lifetime. Another limitation of the Grätzel cell is the relatively weak and narrow spectral response. The cell absorbs almost no light in the near-infrared and infrared regions, where most of the sunlight energy is. Compounds used in Grätzel cells include

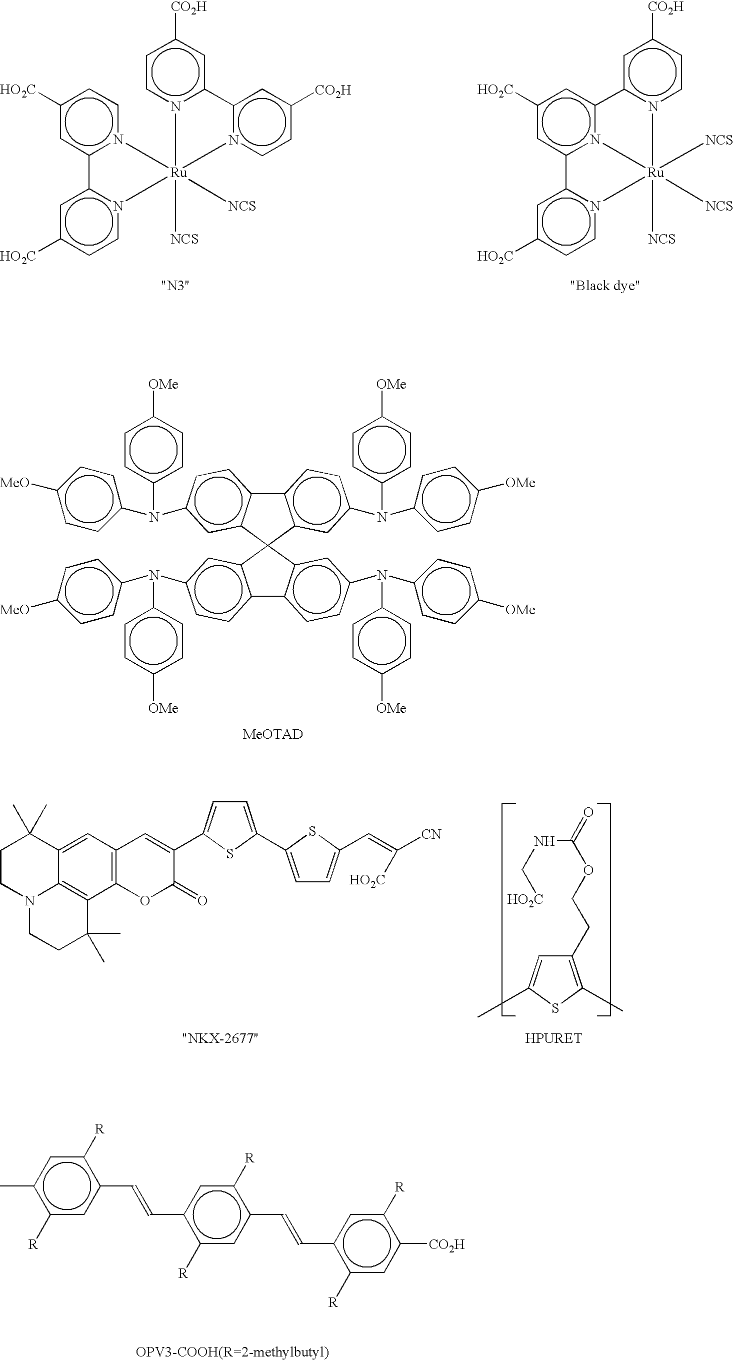

Numerous attempts to solidify the iodine/triiodide electrolyte, for example by gelation with poly(ethylene oxide) derivatives, with poly(vinylidenefluoride-co-hexafluoropropylene) (PVDF-HFP), or with silica nanoparticles, were reported; cell efficiency decreased from 10.4 to 2.6-7.0%. A variety of other hole conductors, including organic polymers and small molecules, were tried in Ru dye-sensitized TiO₂ cells. The best efficiency of 1.7% was reported for spiro-bis(fluorene) derivative MeOTAD. Further optimization of the dopant levels and silver ion coordination of carboxylic acid groups of the Ru dye pushed the efficiency to 3.2%. Introduction of polymers, usually polythiophenes, into the Ru-dye sensitized cell resulted in a low efficiency (0.16% for poly(3-octylthiophene).

Compounds other than Ru complexes were also introduced into the Grätzel cell-like photovoltaics. The tetra(4-carboxyphenyl)porphyrin (TCPP) yields 3.5% efficiency with liquid electrolyte. A variety of coumarine-based dyes having an extended π-conjugated system through polyene or, most recently, bithiophene moieties, afforded efficiencies of 6.0-7.7% (IPCE above 70%). Very recently, conjugated polymers and oligomers were reported as efficient sensitizers in Grätzel cells. Thus, a carboxylated polythiophene derivative poly[2-(3-thienyl)ethanol hydroxyl carbonyl-methylurethane] (HPURET) yielded 1.5%-efficient cell, while PPV trimer (OPV3-COOH) exhibited 55% IPCE.

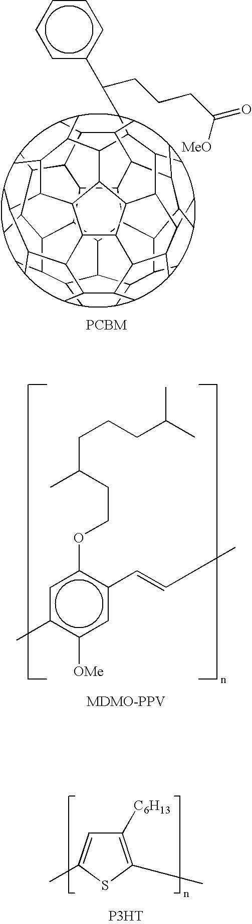

The efficiency of fully organic solar cells remained very low until very recently, when buckminsterfullerene derivatives were introduced as an n-type charge-collection network dispersed in the p-type organic polymer matrix. The efficiency of such bulk heterojunctions cells reaches 2.5% (50% EQE) for the blend of 6,6′-phenyl-C₆₁ butyric acid methyl ester (PCBM) with poly[2-methyl-5-(3′,7′-dimethyloctyloxy)-p-phenylenevinylene] (MDMO-PPV), and 3.5% (70% EQE) for the blend of PCBM with poly(3-hexylthiophene) P3HT). The fabrication of such cells can be done by solution processing on large-area substrates, at room temperature, or slightly above. The composite organic films also adapt ell to the flexible substrates. Thus, the issues of portability and flexibility are much less of a problem as they are for the conventional silicon-based photovoltaics. The limiting factors for such devices are the relatively narrow spectral window of currently used materials, and, perhaps, the intrinsic low electron mobility of the organic materials (typically, below 10⁻⁴ cm² V⁻¹ s⁻¹).

Inorganic n-type semiconductors typically have much higher electron nobility than organic materials. Combination of these materials with organic p-type semiconductors, whose hole mobility can be as high as 0.1 cm² V⁻¹ s⁻¹ (in thin-film transistor configuration), can potentially improve the overall efficiency. Inorganic materials with either wide (i.e. TiO₂) or narrow (i.e. CdSe) bandgap can be used. In the former case, the organic component acts as both sensitizer and the hole transporter, the inorganic component is only the electron transporter. In the latter case, light harvesting is shared between the components.

When an unsensitized Grätzel-type TiO₂ electrode is combined with p-type poly(3′-undecyl-2,2′-bithiophene), efficiencies were as low or even lower than in the presence of the Ru dye, up to 0.1%. More porous TiO₂ films, melt-filled with poly(3-hexylthiophene) exhibited higher efficiencies, up to 0.5% (EQE up to 15%). Probable reasons for relatively low efficiency include insufficient electronic coupling between polymer and the titania, surface traps on TiO₂ surface, diminished mobility of the polymer constricted in the pores compared to the bulk polymer, etc. However, titania is non-toxic and very cheap, and the organic polymer can be solution-processed. Thus, the TiO₂/conducting polymer interface is very promising.

Recently, a new method of making a conducting polymer:TiO₂ heterojunction was reported. MDMO-PPV was combined with Ti(O-i-Pr)₄ in organic solvent and then deposited onto the conducting glass electrode. Slow hydrolysis of the inorganic precursor into TiO₂ afforded ca. 50 nm phase separation domains. The photovoltaic cell based on this bulk heterojuunction was 0.18%-efficient (EQE was 11%).

Hybrid solar cells containing CdSe nanorods and P3HT were recently reported to have a power conversion efficiency of 1.7% and EQE of 59%. The high fraction of CdSe rods (90% w/w) ensured an almost continuous network of n-type material suspended in the p-type polymer matrix. The interface between inorganic and organic components is far from the ideal, very intimate one. The hybrid CdSe/conducting polymer cell can be solution-processed; however, the toxicity of CdSe is likely to limit the widespread use of such cells.

### BRIEF SUMMARY OF THE INVENTION

In one aspect the invention comprises novel polydispersed thiophene homopolymers (formula A below) or copolymers (formula B below) having at least one functional group such as an amino, thiol, phosphine, phosphonic acid, or carboxyl group. In some embodiments of this aspect of the invention the functional group is a terminal group on the polymer; in others, it is located as a substituent on one or more internal thiophene moieties, as shown. The functional group of Formula A polydispersed polymers generally has the formula —(CH₂)ₙZ, in which n is 0-6 and Z is NH₂, NHR², N(R²)₂, SH, P(O)(OH)₂, OP(O)(OH)₂, P(O)(R²)₂, P(R²)₂, COOH, or pyridyl in which R² is an aliphatic group having from 1 to 8 carbon atoms and is optionally substituted. The group —(CH₂)ₙZ may be bonded directly to an atom in the thiophene ring or may be linked to the ring via an alkylene (such as methylene, ethylene, etc.), alkenylene, alkynlene, thienyl, or phenyl group etc.

General formulas of such polymers are

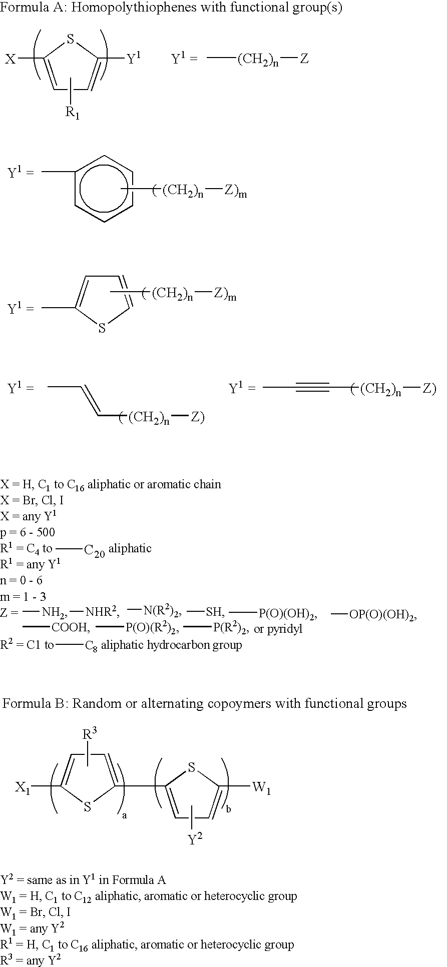

The term “aliphatic or aromatic chains” includes optionally substituted aliphatic groups (including aliphatic groups substituted by optionally substituted aromatic or heterocyclic groups, as described herein), as well as chains of aromatic groups such as biphenylene and the like.

In another aspect the invention comprises novel polydispersed substituted thiophene polymers (including homopolymers, random or alternating copolymers) that contain thermally removable solubilizing groups, notably alkyl ester or alkyl carbonate groups. Such polymers have the general formula (C):

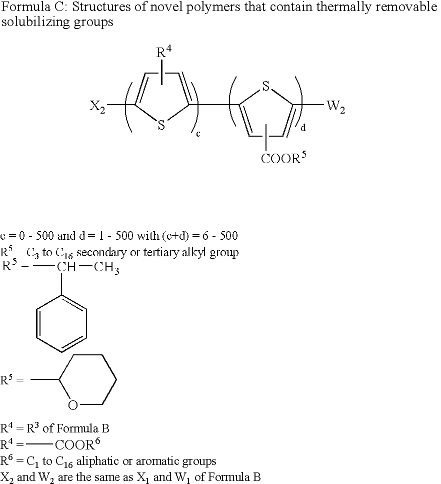

Other aspects of the invention include devices, including photovoltaic devices, transistors, semiconductor devices, light emitters, and the like containing polymers of one of the above types. Yet other aspects of the invention include thin films comprising a thiophene polymer or copolymer of one of the above types.

Another aspect of the invention comprises a process for producing a film or device in which a polydispersed polymer having the formula 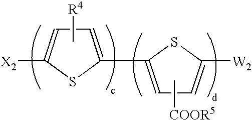
is incorporated into the film or device, wherein the group —COOR⁵ of the polymer assists in solubilization of the thiophene polymer, and in which the device is subsequently heated to remove the alkyl portion (R⁵) of the —COOR⁵ group, leaving behind a thiophene polymer substituted by carboxyl moieties.

As used herein, “aliphatic” means a straight or branched chain acyclic, hydrocarbon radical, or combination thereof, which may be fully saturated, or mono- or polyunsaturated having the number of carbon atoms designated (i.e. C₁-C₁₀ means one to ten carbon atoms). Examples of saturated acyclic aliphatic groups (also termed alkyl groups) include, but are not limited to, groups such as methyl, ethyl, n-propyl, isopropyl, n-butyl, t-butyl, isobutyl, sec-butyl, homologs and isomers of, for example, n-pentyl, n-hexyl, n-heptyl, n-octyl, and the like. An unsaturated aliphatic group is one having one or more double bonds or triple bonds. Examples of unsaturated acyclic aliphatic groups include alkenyl and alkynyl groups such as vinyl, 2-propenyl, isopropenyl, crotyl, 2-isopentenyl, 2-(butadienyl), 2,4-pentadienyl, 3-(1,4-pentadienyl), ethynyl, 1- and 3-propynyl, 3-butynyl, and the higher homologs and isomers.

“Aromatic” or “aryl” refers to the typical substituted or unsubstituted non-aliphatic hydrocarbyl groups of this class, i.e., a polyunsaturated, typically aromatic, hydrocarbon substituent, which can be a single ring or multiple rings (up to three rings) which are fused together or linked covalently, such as phenyl, naphthyl, and the like. This class of moieties also includes fused-ring moieties such as indanyl, etc.

“Heterocyclic” refers to saturated or unsaturated cyclical moieties containing carbon atoms in the ring and additionally one or more hetero atoms, which are typically oxygen, nitrogen, sulfur and/or phosphorus, such as pyridinyl, piperidinyl, pyrrolidinyl, morpholinyl, pyranyl, thienyl, furyl, thiazolyl, and fused-ring moieties such as benzoxazolyl, benzthiazolyl, etc. These may be optionally substituted with one or more substituents such as halogen, hydroxy, optionally substituted lower alkyl and optionally substituted lower alkoxy. Heterocyclic groups include heteroaromatic groups, and heteroaliphatic groups. Heteroaromatic groups are analogous to aromatic groups and include, for example, pyridyl, pyrimidinyl, pyrazolyl, pyrazinyl, thiazinyl, thienyl, furyl, imidazolyl, pyrrolyl, benzoxazolyl, benzthiazolyl, quinolyl, etc. Heteroaliphatic groups are saturated or partially unsaturated, and include, for example, pyrrolidinyl, morpholinyl, pyranyl, etc.

Aliphatic and aromatic groups in compounds of this invention may be unsubstituted or may have one or more substituents, providing that such substituents do not interfere with the desired properties of the polymers or react with each other (such as acidic and basic substituents). Substituents may include, for example, halo, hydroxyl, thiol, nitro, amino, substituted amino, amide, substituted amide, alkoxy, haloalkoxy, alkylenedioxy, alkyl, haloalkyl, hydroxyalkyl, sulfonyl, and the like.

Substituted aliphatic groups also include arylalkyl groups, namely alkyl groups subsisted by one or more aryl groups; for instance, benzyl, phenethyl, triphenylmethyl, and the like. The aromatic ring or rings in the arylalkyl groups may be further substituted similarly to other aromatic groups, e.g. chlorobenzyl, methylbenzyl, etc. Substituted aliphatic groups also include alkyl groups substituted by one or more optionally substituted saturated or unsaturated heterocyclic groups, e.g., pyridylmethyl, pyridylmethyl, piperidinylmethyl, pyrrolidinylmetlhyl, morpholinylmethyl, quinolylmethyl, etc, or by one or more optionally substituted cycloaliphatic groups such as cyclopropylmethyl, cyclohexylmethyl, cyclobutylmethyl, cyclopentylmethyl, cyclohexenylmethyl, cyclohexadienylmethyl, and the like. Such groups may be substituted, for example by one or more halogens, hydroxyl groups, lower alkyl groups, or lower alkoxy groups (including combinations of such groups), providing the substituents do not interfere with the desired properties of the polymers or react with each other.

### BRIEF DESCRIPTION OF THE DRAWINGS

FIG. 1 contains transmission electron microscopy (TEM) images of films containing CdSe and several polymers of the invention.

FIG. 2 depicts power conversion versus volume ratio of CdSe in the active layer of devices made using a polymer of the invention.

FIG. 3 depicts an MS spectrum of a polymer according to the invention.

FIG. 4 depicts TEM images of thin films containing CdSe and polymers of the invention.

FIG. 5 depicts TEM images of thicker films containing CdSe and polymers of the invention.

FIG. 6 depicts IR absorption of films containing a polymer of the invention, before and after heating.

FIG. 7 depicts a TGA of a polymer of the invention after heating.

FIG. 8 depicts a typical configuration of a photovoltaic cell.

### DETAILED DESCRIPTION OF THE INVENTION

In general, this invention relates to the development of electroactive polydispersed polymers such as thiophene polymers or copolymers that are functionalized at one or more chain ends or having functionalities pendant from the polymer chain that affect one or more of the properties of the polymers, i.e. one or more of the physical, chemical, optical, electronic, complexing and interaction properties of the polymers with other organic or inorganic materials, thereby affecting their performance in devices such as photovoltaic cells, light emitters, or transistors. Unexpectedly, the use of these functional polymers in combination with other device components leads to a vast improvement in the performance of devices in which they are incorporated, as measured, for example, by their ability to absorb and/or convert radiation energy into electricity.

The polymers of this invention are polydispersed polymers, that is, they are substantially composed of polymer molecules that have a distribution of molecular weights—as opposed to monodisperse polymers, or oligomers, in which the polymer molecules are substantially identical, having substantially the same molecular weight. The term “substantially” is used in this connection, because, due to the intrinsic nature of polymerization or oligomerization chemistry, in a monodisperse polymer there will be a small percentage of molecules that are different from the great majority, while in a polydisperse polymer there will be a small number of molecules, perhaps as much as 5%, whose chain length or molecular weight will be less than the minimum value for a stated range.

### Polythiophenes Containing Polar Groups that Interact with the Interface Between the Polymer and Organic Material

The following describes the functionalized poly(thiophenes) of this invention and their incorporation in a specific type of organic-inorganic hybrid solar cell, as well as a comparison of the performance of the resulting cells with cells prepared with a very similar but unfunctionalized polymer. This specific type of cell includes CdSe (or CdTe) nanocrystals or nanorods as the inorganic component as described earlier by Alivisatos et al. in U.S. published patent application 2003/0226498 for cells made with unfunctionalized polythiophenes and longer nanorods of CdSe. The performance of the cells made with the functionalized polythiophenes far exceeds that of comparable cells made with ordinary polythiophenes (and, more specifically, with poly3-hexylthiophene). While this reduction to practice with CdSe nanocrystals is elaborated in detail, our invention is not limited to photovoltaic devices including CdSe nanocrystals, but is also applicable to many other types of hybrid solar cells, including, for example, those with titanium dioxide, zinc oxide, tin oxide or other analogous inorganic semiconducting material either in nanocrystalline form or in nanoporous, columnar porous, or flat surface arrangement.

π-Conjugated polymers are being developed as alternatives to traditional inorganic semiconductors for low-cost electronic or optical devices due to the ease of their solution processing and their mechanical flexibility. Such efforts are well exemplified by the intense research and development in organic and organic-inorganic hybrid solar cells. In these types of devices, the active layer is a solution processed mixture of an electron donor phase (a π-conjugated polymer such as regioregular poly(3-hexylthiophene) (P3HT)) and an electron acceptor phase (e.g., CdSe nanocrystals or a fullerene derivative). Since the blending morphology of the mixture can dramatically affect device performance a number of methods have been pursued to obtain a favored three-dimensional interpenetrating network in organic photocells, such as the use of soluble “double cable” materials, covalent or hydrogen bonded molecular dyads or tryads. However, much development is still needed to prepare intimate nanocomposites of conjugated polymers and semiconductor nanocrystals in hybrid solar cells. Although organic surfactants can facilitate the dispersion of nanocrystals in polymers, their presence severely reduces the device efficiency by impeding the transfer of charges between nanocrystal and polymer, as well as the transport of electrons between adjacent nanocrystals. While surfactants can be stripped from the nanocrystals during film processing to afford direct contact between the nanocrystals and the polymer, it is difficult to control the morphology and dispersion of nanocrystals within the polymer when using this process. In one aspect, however, this invention provides end-functional polythiophenes that are very effective in dispersing CdSe or CdTe nanocrystals to afford intimate nanocomposites with favored morphology, and result in improved performance of P3HT/CdSe hybrid solar cells.

In a recent study, an electroactive pentathiophene surfactant with only five thiophene rings linked in an oligomer and containing a phosphonic acid head group was designed and shown to provide strong binding to the surface of a CdSe nanocrystal and facilitate charge transfer between the nanocrystal and an organic semiconducting matrix. However this oligomer could not be used in a photovoltaic cell. Other researchers have also shown the importance of intimate binding between semiconductor particles and molecular adsorbates, i.e., between TiO₂ and molecular dyes for ultrafast interfacial electron transfer. Thus, surface chelation of the TiO₂ surface by the appropriate functional groups on modified dyes leads to the good electronic coupling between the LUMO of the photoexcited dye and the 3d orbital manifold of TiO₂ sites. Moreover, when —COOH groups of the dye coordinate to the surface of TiO₂, the energy of the surface states increases, eliminating the sub-conducting band trap sites. Recently, conjugated polymers and oligomers containing carboxylic acid groups were shown to be efficient sensitizers of nanocrystalline TiO₂.

One embodiment of the invention is an end-functional polythiophene, which has been found to be very effective in dispersing CdSe or CdTe nanocrystals to afford intimate nanocomposites with favored morphology. The use of this functional polythiophene has produced of CdSe hybrid solar cells that demonstrate improved performance. The functional polythiophene can contain the functional group at either or both ends.

The model end-functional poly(3-hexyl-thiophene) P3HT (compound 4) was prepared as shown in Scheme 1 below. P3HT with a Br chain-end (1) was synthesized through a modified McCullough route according to published procedures. Stille coupling reaction of polymer 1 with an organotin compound bearing a cyano group (2) affords polymer 3, which was transformed into 4 after reduction with lithium aluminum hydride. The success of the synthesis was confirmed by NMR analysis and MALDI-ToF mass spectral characterization.

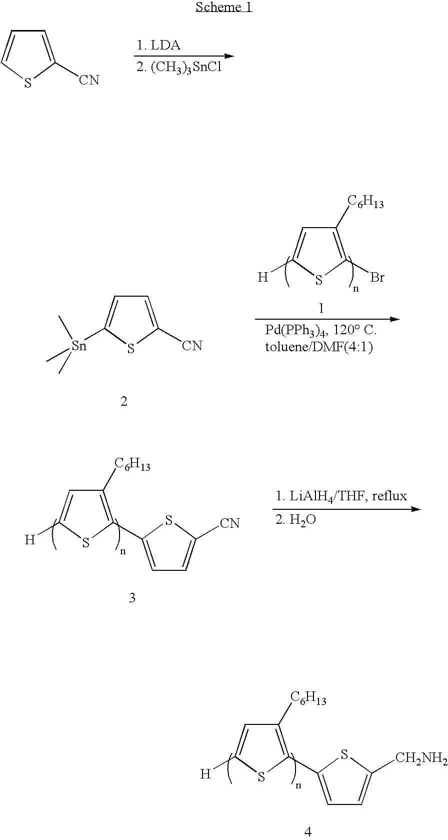

The following demonstrates the incorporation of functionalized poly(thiophenes) in a specific type of organic-inorganic hybrid solar cell, and a comparison of the performance of the resulting cells with cells prepared with a very similar but unfunctionalized polymer. This specific type of cell includes CdSe (or CdTe) nanocrystals or nanorods as the inorganic component as described earlier by Alivisatos et al. for cells made with unfunctionalized polythiophenes and longer nanorods of CdSe. The performance of the cells made with the functionalized polythiophenes far exceeds that of comparable cells made with ordinary polythiophenes (and, more specifically, poly3-hexyl thiophene). Wile this reduction to practice with CdSe nanocrystals is elaborated in detail, our invention is not limited to photovoltaic devices including CdSe nanocrystals, but also to many other types of hybrid solar cells including for example those with titanium dioxide, tin oxide or other analogous inorganic semiconducting material either in nanocrystalline form or in nanoporous, columnar porous, or flat surface arrangement.

Composites of polymer 4 and CdSe nanocrystals were prepared using a procedure modified from one published earlier. CdSe nanorods about 7 nm in diameter and 35 nm in length—as estimated from their imaging by Transmission Electron Microscopy (TEM)—were synthesized by the injection of CdO and Se solution into a mixture of trioctylphosphine, trioctylphosphine oxide (TOPO), and tetradecylphosphonic acid (TDPA), following a protocol derived from published procedures. The TOPO and TDPA ligands on the surface of the nanocrystals were then replaced by refluxing the particles in pyridine. After precipitation in hexane and recovery by centrifugation, the nanocrystals were redispersed in a mixture of chloroform/pyridine (90:10, v/v), and mixed with a solution of functional polymer 4 in the same solvent mixture to afford a co-solution. Nano-composite films were then obtained by spin-coating from this co-solution of 4 and the nanocrystals.

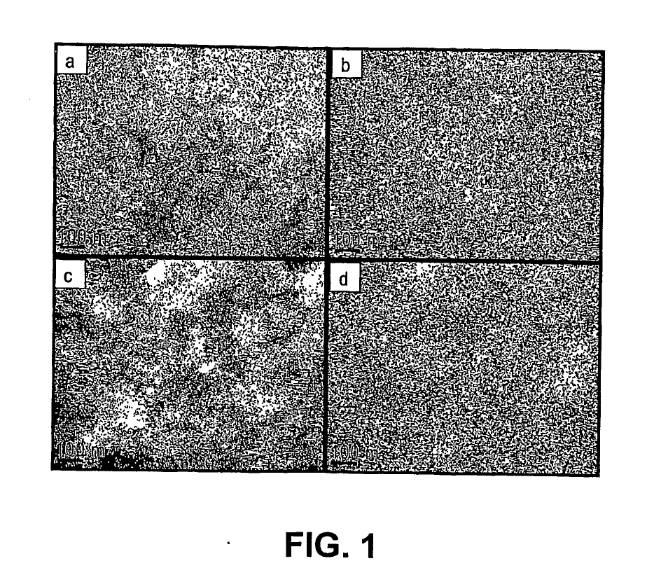

The morphology of the composite films was studied using transmission electron microscopy (TEM). FIG. 1-b, d show two typical TEM images of films of the spun-cast composite of CdSe with polymer 4. Unexpectedly the TEM images show that the nanocrystals are homogeneously dispersed in the polymer matrix and that essentially no aggregation domains can be seen. This is in sharp contrast with films prepared under the same processing conditions from the co-solution of the very same batch of nanocrystals and polymer 1, which itself was the direct precursor of polymer 4. In this case very large domains of phase segregation are seen in the TEM (FIG. 1-a, c), indicating poor dispersion of nanocrystals in the unfunctionalized polymer. This significant morphology difference is always observed, except when the concentration of CdSe is extremely high (>65 vol. %). It appears that even the introduction of a single interacting functionality on the P3HT chain can change drastically its ability to mix intimately and act as a dispersant for CdSe nanocrystals. A similar finding is made with CdTe nanocrystals.

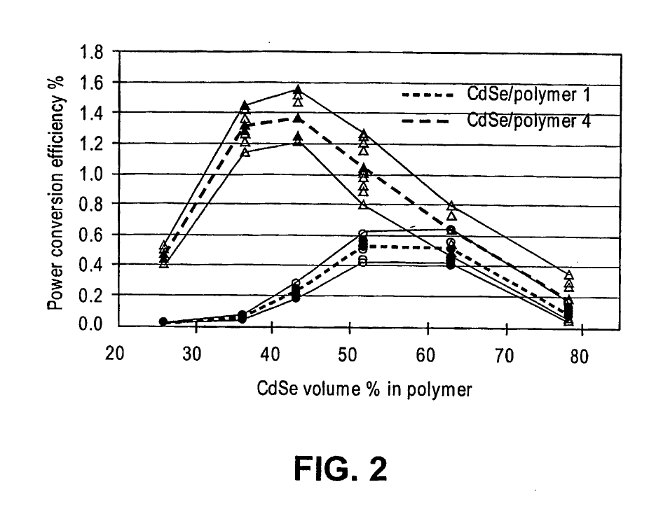

A plot of the AM 1.5 power conversion efficiency versus the volume ratio of CdSe nanocrystals in the active layer for each type of devices is shown in FIG. 2. When the volume ratios of nanocrystals and polymer in the active layer are the same, devices made using polymer 4 exhibited significant increases in power efficiency as compared to those made using polymer 1. In the case of polymers 4 and 1 only a small difference in one end-group exists yet it affects the dispersion of the nanocrystals in 4 and translates into significant differences in performance. The UV/Vis analysis of the active layer films made using 4 and 1 showed that their optical transmission spectra were essentially identical. This suggests that the enhanced performance of devices made using 4 is due to the unique morphology in confers to active layers obtained by mixing inorganic nanocrystals. The plots in FIG. 2 also indicate that the efficiency enhancement achieved by using polymer 4 is especially substantial at lower concentrations of CdSe. This is consistent with the TEM observation that the morphology contrast is more significant at relatively low ratio of CdSe to polymer.

The morphology and device performance improvements discussed above appear to be directly related to the presence of an amino end group in polymer 4 since this end-group is the only significant difference between the two polymers. Though this is unexpected, it may be that polymer 4 partially replaced the pyridine surfactant on the surface of the nanocrystals through coordination of the amino end-group, thereby enhancing the miscibility of the polymer and the nanocrystals. The improvement of device performance displayed in FIG. 2 could be explained by the larger interfacial area for exciton charge separation due to the good dispersion of CdSe in polymer 4. FIG. 2 also reveals that the most favored ratio of CdSe in the film made using 4 is about 40 vol. %, which is lower than that (˜65 vol. %) made using 1 This could also be due to the suppression of nanocrystal segregation by polymer 4 that allowed us incorporate relatively higher ratio of polymer and still retain the continuous interpenetrating network of nanocrystals. This finding suggests that the use of certain types of end-functional P3HT could be a general method to obtain more efficient as well as more “plastic” hybrid photocells. Given the results published previously by Alivisatos et al. it is clear that further optimization involving for example the control of the shapes of the nanocrystals together with functionalized electroactive polymers would lead to additional performance enhancements.

The use of end-functional conjugated polymers provides a general tool to control the morphology and optimize the efficiency not only in polymer/nanoparticle photovoltaic devices, but also in other composite electronic devices, such as LEDs and photodetectors.

The same effect can be observed with other types of functionalized electroactive polymers. For example, a P3HT containing twin amine moieties at one of its chain extremities also shows excellent performance (better than the unfunctionalized P3HT and generally equal to or superior to that of P3HT with only one amine moiety) in CdSe or CdTe solar cells. The same is true for P3HT containing interacting functionalities such as amine groups at both chain ends. Enhanced performance is also seen for polymers containing functionalities pendant from the main chain. These functionalities may either be single or multiple, spread evenly or randomly through the main-chain, or applied in block copolymer fashion.

In addition to amine functionalities, other interacting groups such as phosphonic acid, phosphoric acid, phosphine oxide, carboxylic acid, alcohol, phenol, thiol, or in general polar substituents all have an effect on the device performance of the polymers in which they are incorporated. For example, electroactive polythiophenes containing one or more carboxylic ester, carboxylic acid, or carboxylate end groups show enhanced performance over the corresponding unfunctionalized polymers in solar cells based on various forms (surfaces, porous structures, nanowires, etc) of TiO₂ or ZnO as the inorganic component.

The concept can be extended to other families of electroactive or conducting polymers with different light absorption properties or bandgap. The concept can also be extended to polythiophenes and other electroactive polymers or copolymers in which at least one interacting substituent is located within the polymer chain as in FIG. I, type B.

### ILLUSTRATIVE EXAMPLES

General information. THE and toluene was dried over Na/benzoquinone and freshly distilled before use. DMF was anhydrous and reagent grade. n-Butyllithium, anhydrous ZnCl₂, Ni(dppp)Cl₂, Pd(PPh₃)₄, 2-cyanothiophene, and trimethyltin chloride were purchased from Aldrich and used as received. All reactions were performed under an atmosphere of N₂ (g). The molecular weight of 1 was determined by SEC in toluene at a flow rate of 1 mL/min using a Waters 996 PDA detector module equipped with two 8.0×300 mm mixed-bed SDV, 5 μm particle size columns (Polymer Standard Service, Germany) thermostated at 35° C. Matrix assisted laser desorption ionization time-of-flight (MALDI-TOF) mass spectrometry was performed on a Perseptive Biosystems Voyager-DE spectrometer using delayed extraction mode and with an acceleration voltage of 20 keV. Samples were prepared from a solution of THF using terthiophene as the matrix.

P3HT with a Br end (1): The procedure is analogous to that published in the literature. To a 100 ml three-necked flask was added THF (60 ml) and diisopropylamine (freshly distilled over CaH₂, 3.1 ml, 22 mmol). The mixture was cooled to −70° C. and n-butyllithium (2.5 M in hexane, 8 ml, 20 mmol) was added. The mixture was warmed to room temperature for 5 min and then cooled to −78° C. This freshly generated LDA was transferred via cannula to a solution of 2-bromo-3-hexylthiophene (5.3 g, 21.5 mmol) in THF (160 ml) at −78° C., and the reaction mixture was stirred at −78° C. for 1 h. Anhydrous ZnCl₂ beads (3.0 g, 22 mmol) were added and the mixture was stirred at −78° C. for about 30 min until the zinc chloride was completely dissolved. The cooling bath was taken away and the reaction mixture was warmed to room temperature. Ni(dppp)Cl₂ (110 mg, 0.21 mmol) was added and the mixture was stirred for 15 min. The mixture was poured into methanol (400 ml) to precipitate the polymer product. The crude polymer was washed/fractionated by Soxhlet extraction with methanol and THF. The THF fraction was poured into methanol and pure polymer product (1.2 g, 36% yield) was obtained as purple solid. GPC: Mₙ=7,600, PDI=1.3.

2-Cyano-5-trimethyltinthiophene (2): To a 250 ml three-necked flask was added THF (60 ml) and diisopropylamine (freshly distilled over CaH₂, 3.0 ml, 21 mmol). The mixture was cooled to −70° C. and n-butyllithium (2.5 M in hexane, 8 ml, 20 mmol) was added. The mixture was warmed to room temperature for 5 min and then cooled to −78° C. To this freshly generated LDA was added 2-cyanothiophene (2.18 g, 20 mmol) via syringe at a period of 2 min. The mixture was stirred at −70° C. for 1 h and trimethyltin chloride (1.0 M in THF, 20 ml, 20 mmol) was inserted via syringe in a period of 5 min. The reaction mixture was stirred at −70° C. for 30 min and then at room temperature for overnight. The mixture was extracted with ether/water twice and the combined organic layer was washed with saturated brine and dried over Na₂SO₄. After removal of solvent, the product (3.9 g, 72%) was obtained by distillation (65° C., 0.05 mmHg). Anal. Calcd. for C₈H₁₁NSSn: C, 35.33; H, 4.08; N, 5.15; S, 11.79; Sn, 43.65. Found: C, 35.30; H, 4.12; N, 5.16; S, 11.78. ¹H NMR (CDCl₃) δ 7.70 (d, J=3.6 Hz, 1H), 7.16 (d, J=3.6 Hz, 1 H), 0.43 (s, 9 H).

P3HT with a cyano end group (3): To a 100 ml three-necked flask was added 1 (0.4 mg, ˜0.054 mmol) and toluene (40 ml). The mixture was stirred at 80° C. until 1 was completely dissolved. To this polymer solution was added 2 (0.6 g, 2.2 mmol), Pd(PPh₃)₄ (0.13 g, 0.11 mmol), and DMF (8 ml). The reaction mixture was warmed to 120° C. and stirred at that temperature for 24 h. The mixture was cooled to room temperature and poured into methanol (200 ml) to precipitate the polymer. The crude polymer was washed/fractionated by Soxhlet extraction with methanol and THF. The THF fraction was poured into methanol (200 ml), filtered, and dried to afford a purple product (0.37 g, 94%). ¹H NMR (CDCl₃) of the polymer product exhibits two doublets at δ 7.58 (J=3.9 Hz) and δ 7.11 (J=3.9 Hz), which correspond to the two protons of the cyanothiophene ring on the end of the polymer. GPC: Mₙ=7,600, PDI=1.29.

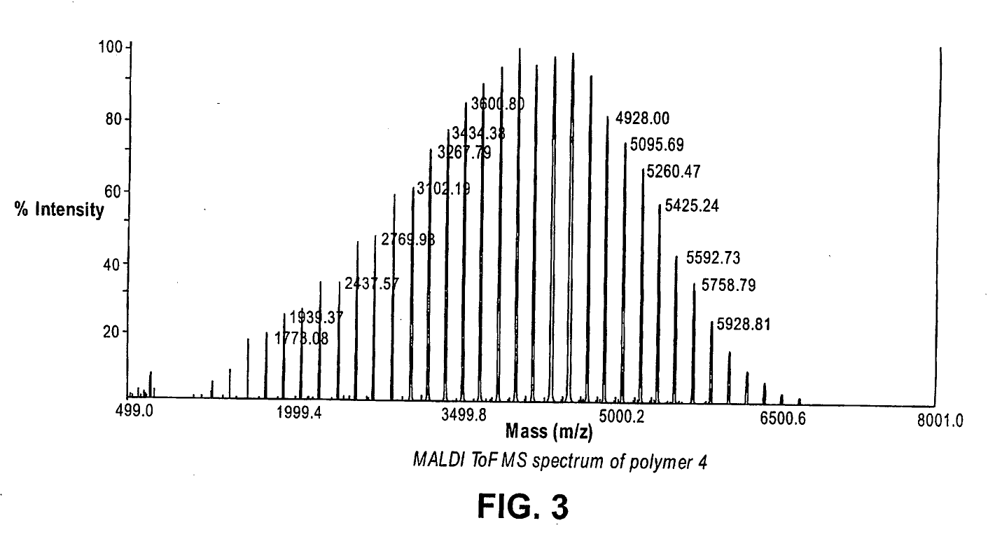

P3HT with an amino end group (4): To a flame-dried flask was added 3 (0.3 g, ˜0.04 mmol) and THF (40 ml). The mixture was stirred at 60° C. until the polymer was completely dissolved. To this polymer solution was added LiAlH₄ (1.0 M in THF, 1.0 ml, 1.0 mmol) and the solution was stirred at reflux overnight. The solution was poured into methanol (300 ml) to precipitate the polymer. The crude polymer was washed/fractionated by Soxhlet extraction with methanol and THF. The THF fraction was poured into methanol (200 ml), filtered, and dried to give a purple solid (0.28 g, 93%). ¹H NMR (CDCl₃) of the product exhibits the end group signals at δ 6.89 (d, J=3.3 Hz, 1 H), δ 6.80 (d, J=3.3 Hz, 1 H), and δ 4.08 (s, 2 H), which confirms the change from the —CN group of 3 to a —CH₂NH₂ of 4. In addition, MALDI-ToF MS (FIG. 3 below) also confirms the expected end group structure. GPC: Mₙ=7,600, PDI=1.30.

CdSe nanocrystals. CdO (0.308 g, 2.40 mmol), tetradecylphosphonic acid (1.336 g, 4.80 mmol) and trioctylphosphine oxide (4.36 g) were loaded into the reaction flask and heated up to 100° C. under argon and degassed for 20 min. The mixture was heated up to 300° C. under argon. After the solution was clear, trioctylphosphine (2.25 g) was added. The solution was stirred for 5-10 min and selenium solution in trioctylphosphine (15 wt %, 1.263 g, 2.40 mmol of Se) was then injected very quickly at 300° C. The temperature of the mixture dropped down to 290° C. and the mixture was kept at 290° C. for 5 min. The mixture was cooled down quickly by the flow of air to the flask wall. Toluene (5 ml) was added into the flask at around 60° C. and the mixture was transferred to a vial in the glove box of argon. The minimum amount of 2-propanol (about 5-7 ml) was added dropwise to the vial stirred vigorously and the mixture was centrifuged for 5 min immediately after the addition of 2-propanol. The supernatant solution was removed with a pipette quickly. The precipitate was re-dissolved in the minimum amount of toluene (about 1 ml), re-precipitated with minimum amount of 2-propanol (about 0.5 to 1 ml). Nanocrystals were obtained as wet precipitates and stored in a glove box as ready-for-use.

Procedure for making co-solutions of nanocrystals and polythiophenes. The whole synthetic batch of CdSe nanocrystals was refluxed in 20 ml of pyridine for 24 hours under argon, and then precipitated with excess hexane, centrifuged and the supernatant solution was discarded. To remove the salt afforded by the pyridine and phosphonic acid, toluene was added to wash the precipitates. The precipitates were then recovered by centrifugation, and dispersed into 2.00 ml of pyridine/CHCl₃ (v/v 1:9). After super-sonication for 5 min, the nanocrystal solution was centrifuged at 3300 rpm for 30-60 min with Fisher Centrific* Model 228 Benchtop Centrifuge and then filtered with a membrane filter (Hydrophobic PTFE 0.45 μm, Millipore Millex-FH). The concentration of the solution was usually between 15 and 20 mg/ml, which was determined based on the weigh after drying of known volume of the solution. This nanocrystal solution was then mixed with the polythiophene solution (15.0 mg/ml) in pyridine/CHCl₃ (v/v 1:9) to afford the co-solution.

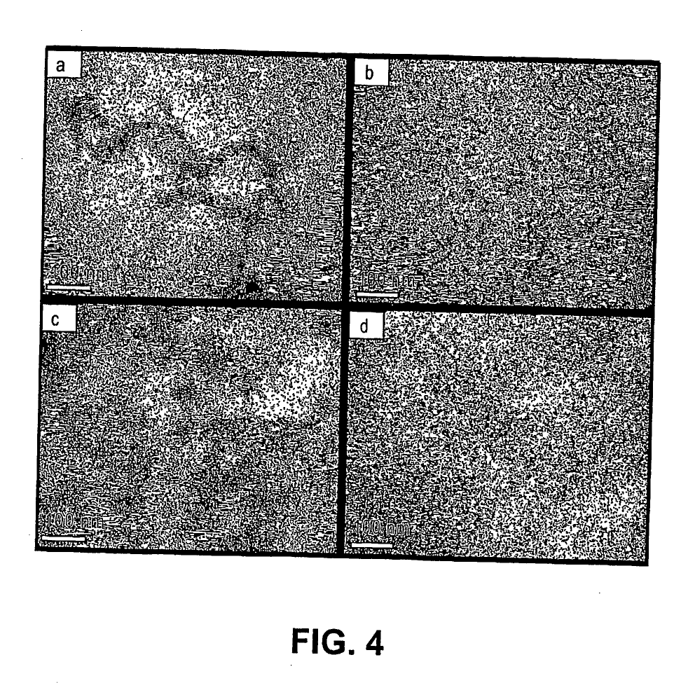

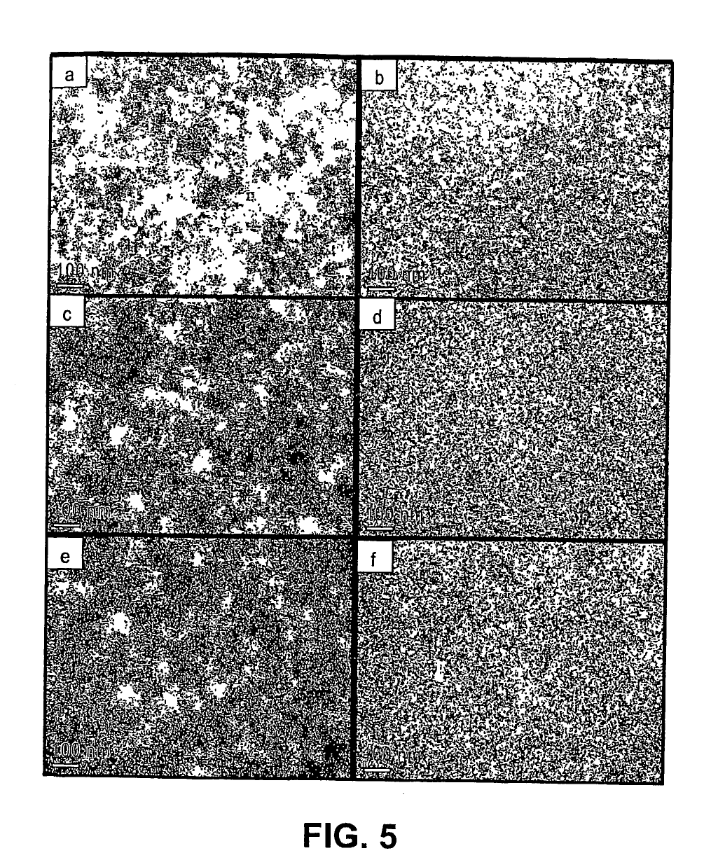

TEM studies. The TEM was performed on thin films using a FEI Tecnai 12 electron microscope operating at 100 kV. TEM samples were prepared by spin coating from the co-solutions of CdSe and polymers (7 mg/ml) onto NaCl substrates. The films were then floated off the NaCl onto the surface of a water bath, and transferred to holey carbon grids. The film thickness was controlled by changing the spin-coating rate. Both thicker (spun at 1000 rpm) and thinner (spun at 2000 rpm) films exhibit better dispersion of nanocrystals in polymer 4 compared to that in polymer 1. FIG. 4 below displays the TEM image comparison of the thinner films, while FIG. 5 shows the comparison of the thicker film made using polymer 1 and polymer 4 respectively.

Procedure for Making Devices.

Indium tin oxide (ITO)-coated glass substrates were cleaned by supersonication in acetone and soap solution for 20 min each and rinsed by de-ionized water, cleaned by supersonication in de-ionized water and 2-propanol for 20 min each, and dried by nitrogen. Finally, the substrates were treated with oxygen plasma for 4 min. A layer of poly(3,4-ethylenedioxythiophene):polystyrene sulfonic acid (PEDOT:PSS) was spun onto the substrate at 3000 rpm for 60 sec and baked at 125° C. for 1 hour under argon. The thickness of PEDOT:PSS was determined to be 60 nm by AFM. The co-solution of nanocrystals and polythiophene was spun onto the substrate at 1000 rpm for 60 sec and then annealed at 150° C. for 1 hour. Aluminum (about 100 nm thickness) was evaporated on the active layer at a rate of 0.3-0.5 nm/sec. The active area of the devices was 0.03 cm².

Measurement of Solar Cell Performance.

The current-voltage characteristics of devices were measured using an Oriel Solar Simulator and a Keithley 236 Source Measure Unit, connected to the solar cell in a homemade airtight holder. All measurements were performed under A.M. 1.5 Global light at an intensity of 100 mW cm⁻². The absorbance of the solar cell was measured with an Agilent Chemstation UV/Vis Spectrophotometer. The solar power conversion efficiency η of the solar cell was calculated according to the following equation:
η=J_{sc}*V_{oc}*FF/I_{light}
where J_{sc} is the short-circuit current density in mA/cm², V_{oc} is the open-circuit voltage and I_{light} is the intensity of irradiating light in mW/cm², and FF (fill factor) is defined as following:
FF=max{J*V}/J_{sc}*V_{oc}
Thiophene Polymers with Thermally Removable Solubilizing Groups

For applications involving semiconductors such as TiO₂ or SnO in photovoltaic systems such as a modified Grätzel cell or photovoltaic systems based on nanoporous titania, or photovoltaic systems based on nanowires, a type of functionalized polythiophene different from those discussed above is used, in which the functional groups of the polymer interact with the inorganic material, enabling better electronic communications in the overall system. Typically, polythiophene is a totally insoluble and intractable material that cannot be used in practice, as it is not possible to process it. For that reason, most researchers in the field use polythiophenes in which some or all of the thiophene rings carry a solubilizing substituent, generally an alkyl group. Poly(3-hexylthiophene) [P3HT] is the most commonly used material available commercially. While the alkyl group is necessary to process the device, its importance is not critical to the operation of the finished device since it does not contribute any significant electronic property or assist in controlling the interface of the polymer with the inorganic material since, for example, the alkyl group does not have a special affinity for TiO₂. This invention thus provides such functional polythiophenes that contain thermally removable solubilizing groups consisting of alkyl esters or carbonates that assist with processing of the device (because the alkyl ester or carbonate acts as a solubilizing moiety) but can later be removed by simple heating once the device is made. Removal of the alkyl solubilizing groups results in a change of the intrinsic electronic properties of the conducting polymer since the insulating alkyl component is largely removed. The energy level of the polythiophene itself may be affected by the presence of a functional group. For example if the ester solubilizing groups (the main components of this part of the disclosure) have their carbonyl functionality located adjacent to the thiophene ring the energy level of the polythiophene is affected, while if the ester functionality is further away from the thiophene ring the energy level of the polythiophene is largely unaffected.

In addition the thermal conversion step that removes the alkyl portion of the solubilizing group may also affect the morphology of the polymer and hence its performance. In addition removal of the alkyl portion of the solubilizing group can have an effect on the intrinsic conductivity of the semiconducting polymer, Finally and as mentioned earlier, the thermally labile solubilizing group can be designed in such a way that it leaves behind a short functionality such as a carboxylic acid that is capable of interacting with the inorganic material thereby improving the interface and the overall performance of a photovoltaic cell made from these components.

For example, the invention relates to several new polythiophenes containing solubilizing and thermally removable ester groups in the 3-position of the thiophene ring. Scheme 2 shows the preparation of one such functional polythiophene (structure 7 below) with removable ester groups, and also shows the thermal removal of the alkyl solubilizing group to afford the insoluble polythiophene (structure 8) with carboxylic acid groups capable of interacting with TiO₂ or SnO₂ or ZnO. 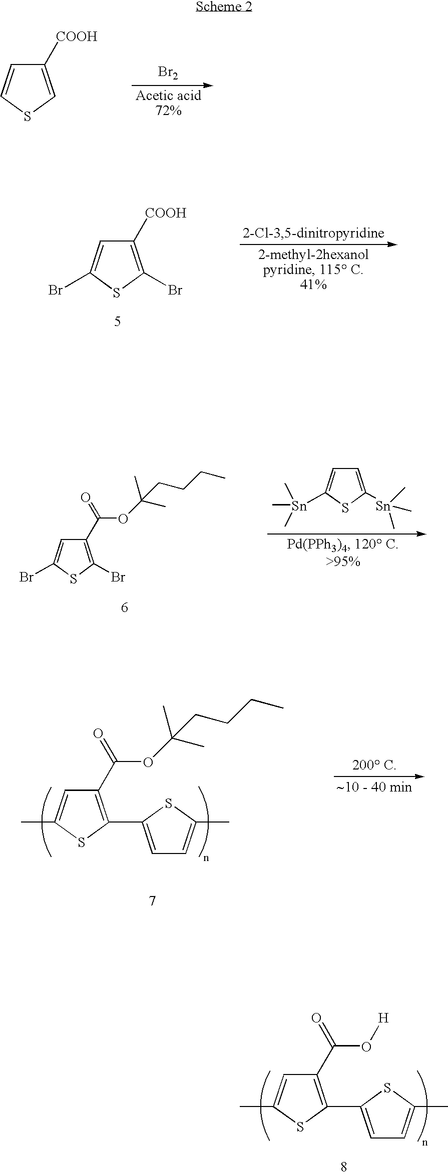
The performance of PV cells made from polymers such as 7 is vastly superior (showing frequently at least two-fold improvement) to the performance of cells made from a regular poly(3 -hexylthiophene).

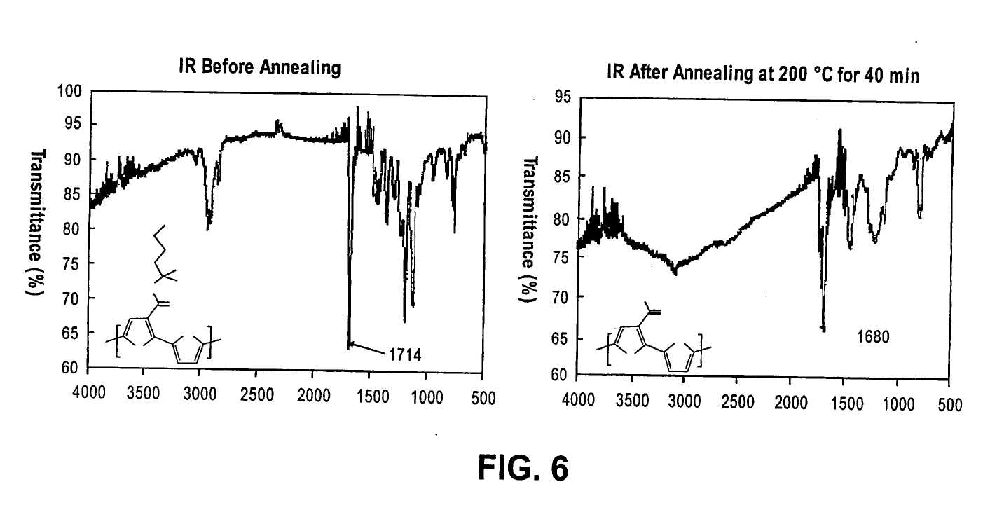

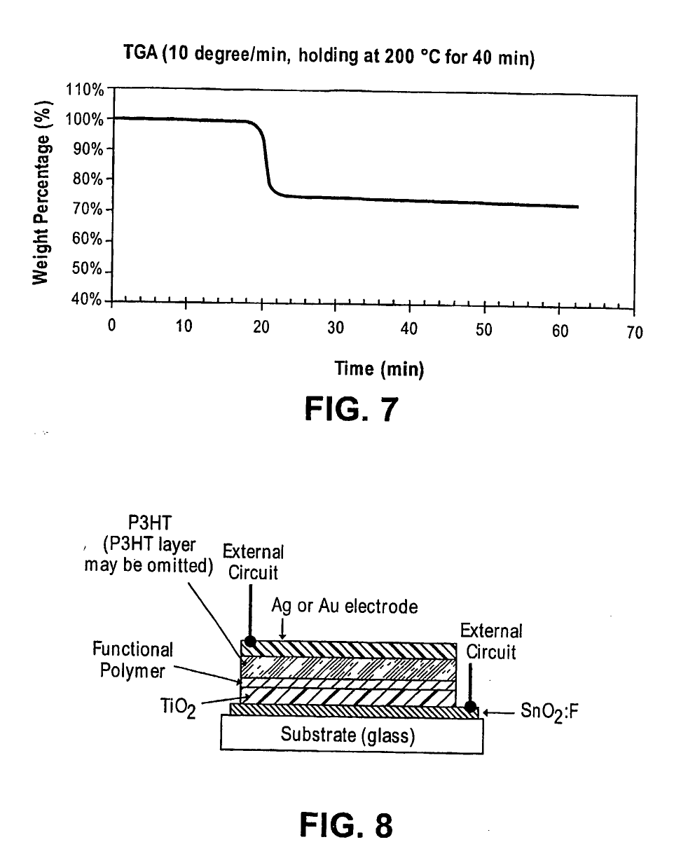

Evidence for the fact that polymer 7 is transformed into 8 is provided by both IR spectroscopy (FIG. 6) and by thermogravimetric analysis (FIG. 7).

FIG. 6 shows the infrared spectrum of polymer 7 before thermal annealing at 200 degrees C and the infrared spectrum after thermal annealing. The characteristic ester peak of polymer 7 disappears during annealing and the infrared spectrum of the product shows features typical of a carboxylic acid rather than an ester. FIG. 7 shows that when polymer 7 is heated to 200° C. a thermal reaction occurs with loss of over 20% of the mass of the polymer as the alkyl group is evolved as a volatile alkene. What is left behind is polymer 8.

Heating of the polymer, or of the film or device containing the polymer, can be done at temperatures of from about 170° C. to about 300° C., preferably from about 190° C. to about 250° C. depending on the particular polymer.

### ILLUSTRATIVE EXAMPLES

2,5-Dibromothiophene-3-carboxylic Acid (5). Thiophene 3-carboxylic acid (2.56 g, 0.02 mol) and glacial acetic acid (50 ml) were put into a 100 ml 3-necked flask equipped with a stirring bar, a condenser, and an additional funnel. Then, Br₂ (5.3 ml, 0.10 mol) was added to the flask drop by drop at room temperature. The mixture was warmed and stirred at 60° C. for 8 h. After the reaction was completed, the mixture was poured into 200 ml of cold water (ice bath) and some Na₂SO₃ was added to decolorize. The mixture was filtered and a light yellow solid was obtained. The crude product was recrystallized from 600 ml of EtOH—H₂O (1:2 v/v) to give 4.8 g (84%) of product 5 as needles. ¹H NMR (CDCl₃): δ 10.88 (s), 7.41(s). 13C NMR: δ 165.3, 132.0, 130.8, 121.4, 111.7.

2-Methyl-2-hexyl-2,5-dibromothiophene-3-carboxylate (6). To a mixture of2,5-dibromo-3-thienylcarboxylic acid (6.0 g, 21 mmol) and 2-methyl-2-hexanol (3.2 g, 27.5 mmol) in pyridine (30 ml) under nitrogen atmosphere was added 2-chloro-3,5-dinitropyridine (4.3 g, 21 mmol). The mixture was stirred at 115° C. for 30 min. After cooling to room temperature, the solution was poured into 6% aqueous NaHCO₃ solution (360 ml) and extracted twice with petroleum ether (2×200 ml). The combined organic phase were washed with water three times (3×150 ml) and dried over anhydrous Na₂SO₄. After removal of solvent, the residue was purified by column employing ethyl acetate/hexane (1:7) as eluent and a light yellow oil was obtained (3.4 g, yield 46%). ¹H NMR (CDCl₃): δ 7.26 (s, 1 H), 1.84 (t, J=6.9 Hz, 2 H), 1.53 (s, 6 H), 1.31-1.36 (m, 4 H), 0.90 (t, J=7.5 Hz, 3 H).

Poly(3-(2-methyl-2-hexylcarboxylate)thiophene-co-thiophene) (7). 2-Methyl-2-hexyl-2,5-dibromothiophene-3-carboxylate (6) (1.00 g, 2.6 mmol) and 2,5-di(trimethyltin)thiophene (1.07 g, 2.6 mmol) were charged into a 100 ml 3-necked flask and Pd(PPh₃)₄ (0.16 g) was then added. The mixture was evacuated then filled with nitrogen and this process was repeated five times. Then, DMF (7 ml) and toluene (30 ml) were added via syringe. The mixture was then heated to 120° C. for 12 h. Subsequently, the reaction mixture was cooled down to room temperature and was poured into 300 ml of methanol. After filtration, the polymer was washed with hexane by Soxhlet extraction for 10 h, followed by Soxhlet extraction using THF. The THF fraction was poured into 300 ml of methanol. The precipitate was filtered and washed with acetone via Soxhlet extraction for 5 h. After drying in vacuum overnight, 0.75 g (95%) of product was obtained.

Poly(3-thienylcarboxylic acid-co-thiophene) (8). Polymer 7 is easily transformed into polymer 8 by simple heat treatment at ˜200° C. for about 10 to 40 min. As an example, polymer 7 can be spin-coated onto a substrate such as TiO₂ or ZnO. Thermal annealing of the film of 7 generates 8 in-situ, Since 8 is now totally insoluble this thermal treatment is performed in the device configuration itself. IR analysis (FIG. 6) reveals that the successful transformation from 7 to 8: the C—H stretch vibration absorption at 2800-3000 in polymer 7 cannot be seen in the spectrum of polymer 8. Instead, a broad absorption from 2000 to 3500, which typically corresponds to —COOH groups, can be seen in polymer 8. In addition, changes are seen in the carbonyl bands as the original ester is transformed into a carboxylic acid. Finally, TGA analysis (FIG. 7) confirms that the mass loss after the heat treatment corresponds to that expected by calculation for the loss of an alkene, indicating the success of the removal of the solubilizing alkyl group with formation of the desired interacting —COOH groups.

FIG. 8 shows the typical configuration of a PV cell made with polymer 8 (thermally transformed from precursor polymer 7). It should be noted here that though a flat surface of TiO2 is shown, this needs not be so and better performance is expected if the surface of contact between the polymer and the inorganic material (e.g. TiO2, SnO₂, ZnO) is increased by introducing porosity in the inorganic, building interpenetrating networks, using the inorganic in the form of nanotubes or nanowires, etc.

It is understood that the examples and embodiments described herein are for illustrative purposes only and that various modifications or changes in light thereof will be suggested to persons skilled in the art and are to be included within the spirit and purview of this application and scope of the appended claims.

All publications, patents, and patent applications cited herein are hereby incorporated by reference in their entirety for all purposes.

What is claimed is:

1. A polymer having the formula

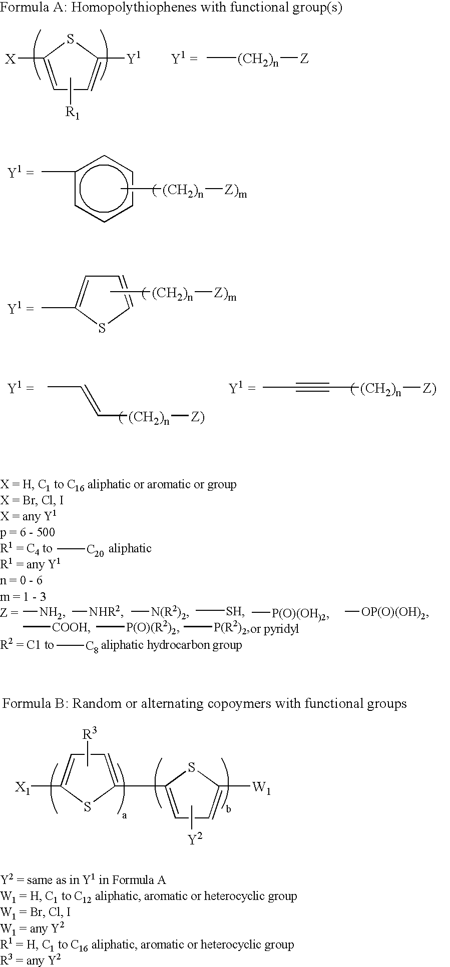

2. A thin film transistor comprising a polymer according to claim 1.

3. An electrically conducting composition comprising a polymer according to claim 1 and an inorganic semiconductor.

4. A composition according to claim 3 in which the inorganic semiconductor is selected from materials comprising cadmium, selenium, technetium, tin, and/or titanium.

5. A composition according to claim 3 in which the inorganic semiconductor is present in the form of nanocrystals.

6. An electronic device comprising a polymer according to claim 1 or a composition according to claim 3.

7. A photovoltaic cell comprising a polymer according to claim 1 or a composition according to claim 3.

8. A photovoltaic cell according to claim 7 wherein the cell is a solar cell.

9. A light-emitting device comprising a polymer according to claim 1 or a composition according to claim 3.

10. A transistor comprising a polymer according to claim 1 or a composition according to claim 3.

11. A nanocomposite film comprising a polymer according to claim 1 or a composition according to claim 3.

12. A method for producing a composition according to claim 3 comprising mixing a solution containing a polymer of claim 1 with one or more solutions containing compounds that are inorganic semiconductors or that react to form inorganic semiconductors.

13. A polymer composition having the formula.

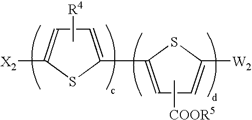

14. A polymer composition having the formula

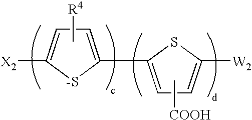

15. A thin film transistor comprising a polymer according to claim 13 or 14.

16. An electrically conducting composition comprising a polymer according to claim 13 or 14 and an inorganic semiconductor.

17. A composition according to claim 16 in which the inorganic semiconductor is selected from materials comprising cadmium, selenium, technetium, tin, zinc, and/or titanium.

18. A composition according to claim 16 in which the inorganic semiconductor is present in the form of nanocrystals or nanorods.

19. An electronic device comprising a polymer according to claim 13 or 14 or a composition according to claim 16.

20. A photovoltaic cell comprising a polymer according to claim 13 or 14 or a composition according to claim 16.

21. A photovoltaic cell according to claim 20 wherein the cell is a solar cell.

22. A light-emitting device comprising a polymer according to claim 13 or 14 or a composition according to claim 16.

23. A transistor comprising a polymer according to claim 13 or 14 or a composition according to claim 16.

24. A nanocomposite film comprising a polymer according to claim 13 or 14 or a composition according to claim 16.

25. A method for producing a thin film transistor that comprises a polymer having the formula 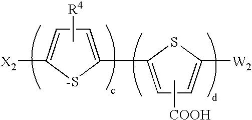
the method comprising:
(a) forming a thin film transistor comprising a polymer having the formula 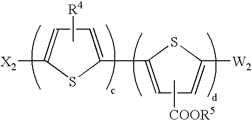
and an inorganic semiconductor; and
(b) heating the transistor of step (a) to a temperature such that the polymer of step (a) is converted to a polymer having the formula (insert formula of polymer after heating).

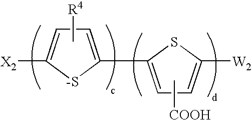

26. A method according to claim 25 in which the heating is conducted at a temperature of from about 170° C. to about 300° C.
